(19) United States
(12) Patent Application Publication
(10) Pub. No.: US 2007/0020840 A1
(43) Pub. Date: Jan. 25, 2007

(54) Programmable structure including nanocrystal storage elements in a trench

(75) Inventor: Gowrishankar L. Chindalore, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: Freescale Semiconductor, Inc.

(21) Appl. No.: 11/188,615

(22) Filed: Jul. 25, 2005

(51) Int. Cl. H01L 21/8238

(52) U.S. Cl. 438/211

(57) ABSTRACT

A storage cell includes a semiconductor substrate defining a trench, a bottom dielectric lining the trench, and a charge storage layer on the bottom dielectric. The charge storage layer includes a plurality of discontinuous storage elements (DSEs). A control gate and a top dielectric cover the DSEs. The storage cell includes a source/drain region underlying the trench. The DSEs may be silicon nanocrystals and the control gate may be polysilicon. The control gate may be recessed below an upper surface of the semiconductor substrate and an upper most of the DSEs may be vertically aligned with the control gate upper surface. The storage cell may include an oxide gap structure laterally aligned with the silicon nanocrystals adjacent the trench sidewall and extending vertically from the upper most of the silicon nanocrystals to the upper surface of the substrate. The DSEs include at least programmable two injection regions.

### FIELD OF THE INVENTION

The invention is in the field of semiconductor devices and, more particularly, nonvolatile storage devices.

### RELATED ART

Nonvolatile storage is an important element in the design of substantially all electronic devices. In the field of wireless and portable electronic devices, nonvolatile storage must be compact and consume little power. Various nonvolatile storage cells have been proposed and implemented. Included among these conventional cells are planar storage cells and storage cells employing floating gates as a charge storage element. A planar storage cell is characterized by a planar transistor channel region typically located in proximity to an upper surface of the wafer substrate. While planar technology is mature and well understood, planar devices consume an undesirably large amount of wafer area.

With respect to the charge storage element, conventional floating gates have been made of a contiguous strip of a conductive material such as polysilicon. Conductive floating gates present a problem in devices with very thin dielectrics. Thin dielectrics are particularly susceptible to pin hole defects. With a conductive floating gate, all of the stored charge on the floating gate can leak off through a single pin hole defect in the dielectric. Moreover, conventional floating gates are not suitable for localized programming in which injected electrons are confined to a specific location of the charge storage element. Localized programming offers the prospect of multiple bit storage cell, where each bit is associated with a specific region of the charge storage element. Accordingly, it would be desirable to implement a multiple bit storage device suitable for use in an advanced processes employing very thin dielectrics where the design of the implemented device consumes less area than planar devices and devices employing conventional charge storage elements.

### BRIEF DESCRIPTION OF THE DRAWINGS

The present invention is illustrated by way of example and not limited by the accompanying figures, in which like references indicate similar elements, and in which:

FIG. 1 is a partial cross sectional view of a wafer at an intermediate stage in one embodiment of a fabrication process in which a hard mask is formed on a dielectric liner over a semiconductor substrate of a wafer;

FIG. 2 depicts processing subsequent to FIG. 1 in which trenches are formed in the semiconductor substrate;

FIG. 3 depicts processing subsequent to FIG. 2 in which the trenches are lined with a bottom dielectric;

FIG. 4 depicts processing subsequent to FIG. 3 in which source/drain regions are formed underlying the trenches;

FIG. 5 depicts processing subsequent to FIG. 4 in which a layer of discontinuous storage elements are deposited over the wafer;

FIG. 6 depicts processing subsequent to FIG. 5 in which a top dielectric is formed on the layer of discontinuous storage elements;

FIG. 7 depicts processing subsequent to FIG. 6 in which a control gate layer is formed in the trenches;

FIG. 8 depicts processing subsequent to FIG. 7 in which the control gate is polished back to form distinct control gates in each of the trenches;

FIG. 9 depicts processing subsequent to FIG. 8 in which the control gates are further processed to create recessed control gates;

FIG. 10 depicts processing subsequent to FIG. 9 in which the hard mask is removed;

FIG. 11 depicts processing subsequent to FIG. 10 in which an isolating dielectric is formed on the recessed control gates;

FIG. 12 depicts processing subsequent to FIG. 1 in which a select gate is formed on the isolating dielectric;

FIG. 13 depicts a hot carrier injection programming table for the storage device depicted in FIG. 7; and

FIG. 14 depicts a source side injection table for the storage device of FIG. 12.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

In one aspect, a semiconductor-based storage cell and a corresponding fabrication process employ a trench etched into a semiconductor substrate and a charge storage layer formed along the sidewalls of the trench. The charge storage layer preferably includes a set of discontinuous storage elements (DSEs). In this embodiment, the DSEs may be silicon nanocrystals, which are small, discreet silicon structures embedded in a dielectric layer and capable of holding a positive or negative charge. Because DSEs are not physically or electrically connected to each other, DSEs are less susceptible to charge loss through pin holes in the dielectric layer than conventional storage elements such as conventional polysilicon floating gate structures. The preferred implementation of the storage device is capable of storing multiple bits of information using hot carrier injection (HCI) programming, source side injection (SSI) programming, or both.

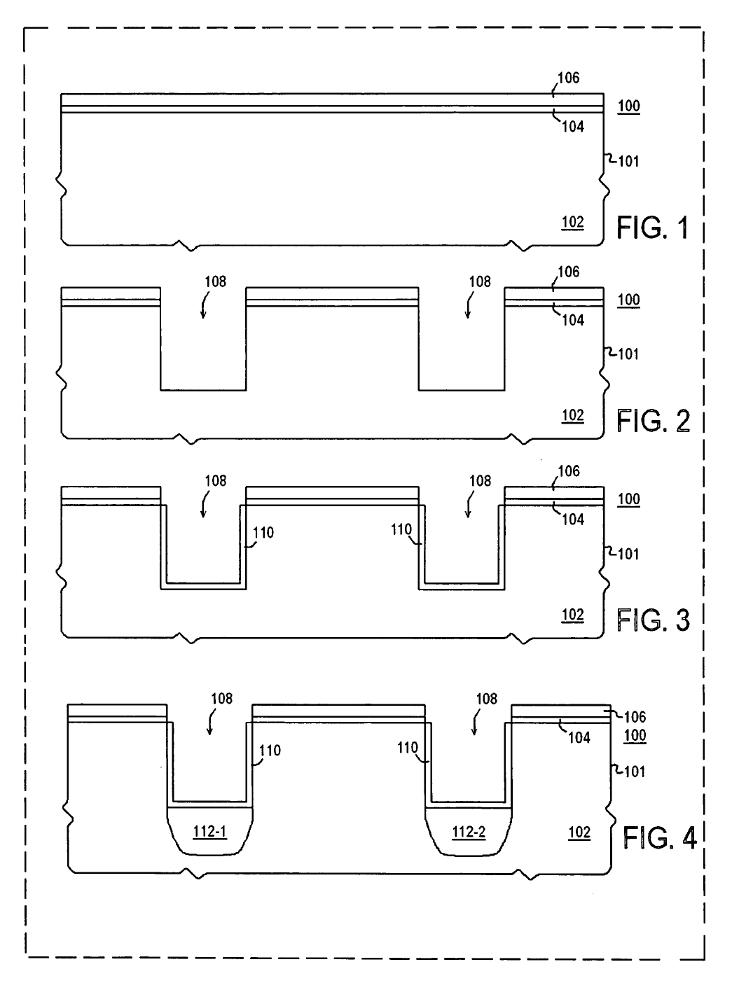

Referring to the drawings, FIG. 1 through FIG. 12 depict a set of partial cross sectional views of a wafer at various stages in process for fabricating an embodiment of a nonvolatile storage device 100. In FIG. 1, a dielectric liner 104 and a hard mask 106 are formed on an upper surface of a semiconductor substrate 102 of a semiconductor wafer 101. Semiconductor substrate 102 is preferably doped or undoped monocrystalline silicon. In other embodiments, semiconductor substrate 102 may include other semiconductors such as germanium or various semiconductor alloys such as the III-V semiconductor alloys including gallium arsenide.

In one embodiment, dielectric liner 104 is silicon oxide, which may be thermally formed (grown) or deposited using CVD (chemical vapor deposition). Hard mask 106 is preferably a dielectric that can be selectively etched with respect to substrate 102. Hard mask 106 is preferably CVD silicon nitride, which is desirable for its ability to prevent oxidation of an underlying semiconductor.

Referring now to FIG. 2, trenches 108 are formed in semiconductor substrate 102. Trenches 108 define the basic structure in which storage device 100 is to be formed. Formation of trenches 108 includes conventional photolithographic patterning of dielectric liner 104 and hard mask 106, followed by a dry etch process that etches the semiconductor material (e.g., silicon) preferentially with respect to liner 104 and hard mask 106. Etch processes of this type are well known in the field of semiconductor fabrication. In the depicted implementation, trenches 108 have an aspect of approximately 12. A depth of trenches 108 is an implementation detail, but trenches having a depth in the range of approximately 50 nm to 300 nm are desirable for wireless applications and other applications requiring a dense storage array.

In FIG. 3, a first step in the formation of a charge storage stack includes the formation of a dielectric, referred to herein as bottom dielectric 110, on sidewalls and the floors of trenches 108. Bottom dielectric 110 is preferably a thin (e.g., 1 nm to 10 nm) high quality dielectric that is employed in the programming and erasing of the DSEs. A thin dielectric is required to achieve adequate programming times using either injection-based or tunneling-based programming techniques. A high quality dielectric is required to withstand the potentially large programming voltages and currents and the potentially large number of programming cycles without exhibiting breakdown or significant leakage. In the preferred embodiment, bottom dielectric 110 is a thermally formed silicon dioxide film having a thickness in the range of approximately 4 nm to 10 nm. In some embodiments, bottom dielectric 110 may include multiple dielectric layers. As depicted in FIG. 3, where hard mask 106 is a silicon nitride hard mask, thermal oxidation of the trench walls does not substantially increase the thickness of dielectric liner 104 even for embodiments in which dielectric liner 104 is a silicon oxide.

In FIG. 4, source/drain regions 112-1 and 112-2 (generically or collectively referred to as source/drain region(s) 112) are formed underlying trenches 108. Source/drain regions 112 are electrically conductive, heavily-doped regions having a conductivity type opposite to a conductivity type of semiconductor substrate 102. For an embodiment employing NMOS storage devices, for example, semiconductor substrate is preferably a lightly doped p-type (p−) silicon and source/drain regions 112 are heavily doped n-type (n+) silicon having an impurity distribution in excess of 1e18 cm⁻³. In one embodiment, source/drain regions 112 are buried diffusion regions formed by implanting an impurity into substrate 102 underlying trenches 108 and thereafter performing a diffusion step ( ). In other embodiments, the implantation step may be omitted to preserve the integrity of bottom oxide 110.

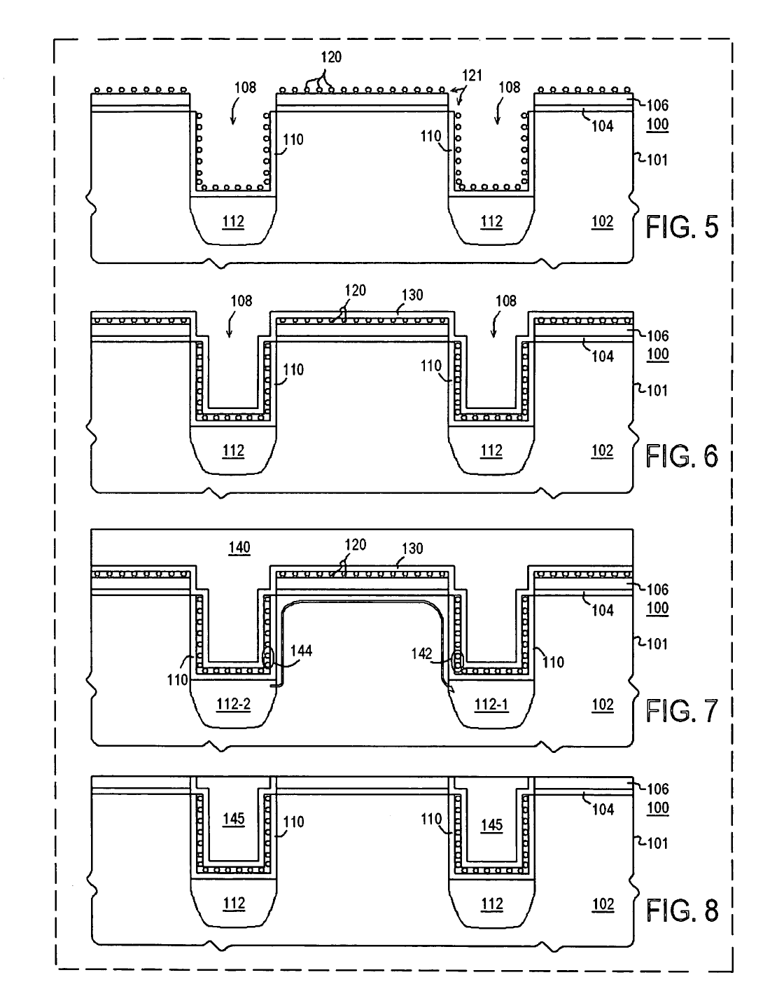

In FIG. 5, a charge storage layer 121 is non-selectively formed on bottom oxide 110 and an upper surface of hard mask 106. Charge storage layer 121 represents the structure in or on which charge will be stored to program or erase the bit or bits of storage device 100. In the depicted embodiment, charge storage layer 121 includes a plurality of DSEs 120. DSEs 120 (also sometimes referred to as nanocrystals) are a set of discreet accumulations of a material capable of storing a charge. Suitable materials include silicon, polysilicon, and dielectrics such as silicon nitride or silicon oxynitride.

In the preferred implementation, DSEs 120 are silicon DSEs (silicon nanocrystals). In this implementation, DSEs 120 may be formed in any one of a variety of ways, preferably without requiring any photolithography steps. One well-known DSE formation technique is to deposit an amorphous silicon layer and heat it to form the nanocrystals. Another technique is to deposit the nanocrystals using chemical vapor deposition (CVD). DSEs may have various shapes, including hemispherical and spherical, depending upon the deposition technique employed. In one implementation, DSEs 120 are approximately 10 nm in diameter and are spaced at a predominantly uniform spacing of approximately 10 nm. Regardless of the formation technique used, each DSE 120 is a particle of silicon that is electrically and physically isolated from its neighbors. Alternative materials, including dielectric materials such as silicon nitride may also be used for DSEs.

Referring to FIG. 6, a top dielectric 130 has been non-selectively formed overlying charge storage layer 121 to complete the formation of a charge storage stack, which includes bottom dielectric 110, charge storage layer 121 (FIG. 4), and top dielectric 130. In the preferred embodiment, top dielectric 130 is a high temperature oxide (HTO) desirable because it exhibits characteristics (e.g., density and dielectric strength) substantially equivalent to thermally formed silicon dioxide. In this embodiment, the HTO may be formed by a conventional HTO process such as reacting dichlorosilane and nitrous oxide at temperatures approaching 900 C. In other embodiments, it may be desirable to employ a lower temperature process (e.g., a TEOS (tetraethylorthosilicate) process) to guard against unintended oxidation of the silicon embodiments of DSEs 120. A thickness of top dielectric 130 is preferably in the range of approximately 5 nm to 10 nm. Top dielectric 130 may include multiple layers of dielectric films.

Referring now to FIG. 7, a control gate layer 140 is formed by non-selectively depositing an electrically conductive control gate material over wafer 101 including within trenches 108 (FIG. 5), planarizing (e.g., by chemical mechanical polish and/or etch back) the deposited control gate material to produce a substantially planar upper surface, and patterning the deposited material using conventional lithography and etch techniques. In one embodiment, control gate layer 140 is formed by conventional CVD of polysilicon. In this embodiment, the polysilicon may be doped either in situ or after deposition using ion implantation. In an embodiment that uses NMOS transistors, for example, control gate layer 140 may be doped with an n-type impurity such as arsenic or phosphorous.

Storage device 100 as depicted in FIG. 7 is a functional nonvolatile storage device. More specifically, storage device 100 as depicted in FIG. 7 is a symmetrical programmable device suitable for employing a hot carrier injection programming technique and capable of storing two bits of information (i.e., four unique states). For NMOS embodiments (in which source/drain regions 112 are n-type and semiconductor substrate 102 is p-type), a first bit of information may be programmed by biasing, through source/drain contacts not depicted in FIG. 7, the first source/drain regions 112-1 to a first programming voltage (V_{P1}), control gate 140 to a second programming voltage (V_{P2}) and grounding second source/drain region 112-2 and semiconductor substrate 102. In one embodiment V_{P1} and V_{P2} are both preferably in the range of approximately 6 V to 9 V. Under these biasing conditions, source/drain region 112-1 serves as the drain and electrons flow from source 112-2 to drain 112-1 along a conductive path formed in an upper portion of substrate 102. As electrons are accelerated by the electrical field resulting from the potential difference between drain 112-1 and source 112-2, they are swept into a depletion region surrounding the biased drain. Some of these highly kinetic electrons collide with atoms in semiconductor substrate lattice and generate electron-hole pairs. Some of the electrons thus generated are injected into charge storage layer 121 by the electric field attributable to the positive bias on control gate layer 140. This hot carrier injection process occurs primarily in a narrow injection zone, represented by reference numeral 142 in FIG. 7, in proximity to drain 112-1 where the electrical field is at its maximum. The DSEs 120 encompassed by injection zone 142 retain injected charges and cause a detectable alteration in the electrical characteristics of the storage device. This alteration can be sensed during a read cycle as a change in IDS. As such, the charge stored on DSEs 120 in injection zone 142 correspond to a first bit of storage device 100.

A second injection zone 144 of charge storage device 100 is programmed by reversing the polarities of the source/drain biases with source/drain 112-2 functioning as the biased drain terminal and source/drain region 112-1 serving as the grounded source terminal. Erasing injection zones 142 and 144 may be achieved by biasing control gate layer 140 to a negative potential (V_{E1}), and biasing semiconductor substrate 102 to a positive value (V_{B2}). The source/drain regions 112 may be floated during the erase operation. In this configuration, the erase operation erases both bits simultaneously by simultaneously removing the stored charge from injection zones 142 and 144.

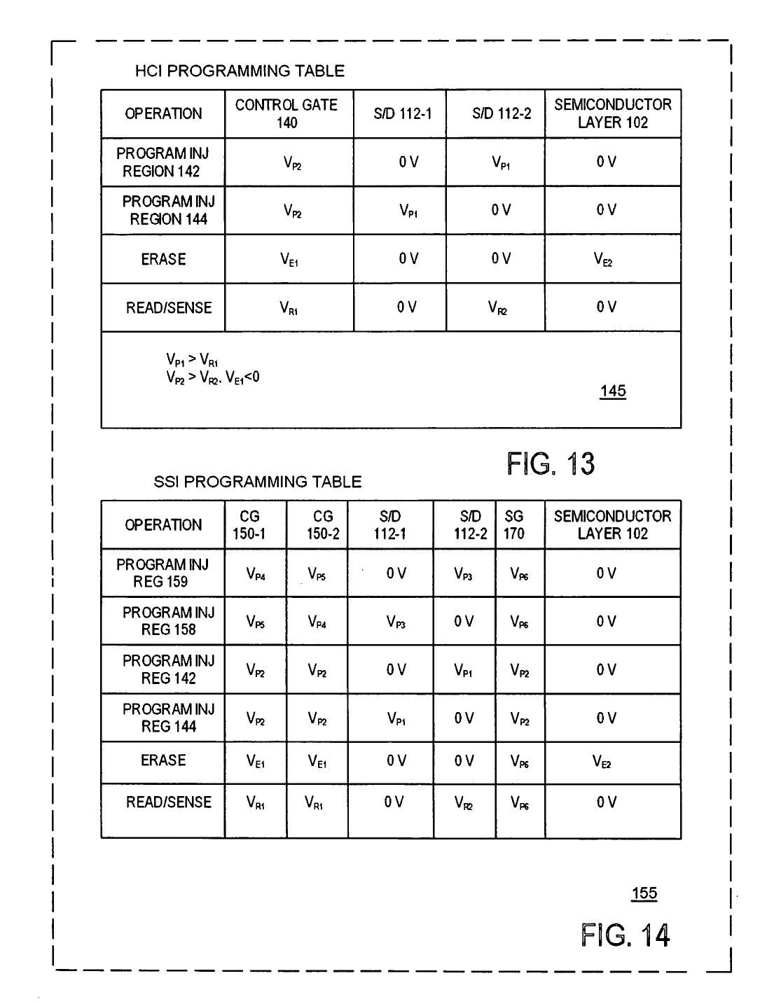

A programming table 145 depicted in FIG. 13 summarizes the bias conditions for program, erase, and read (sense) operations with respect to storage device 100 as depicted in FIG. 7. The read operation uses a biasing configuration analogous to the programming biasing configuration, but using lower voltages. The magnitudes of the various biasing voltages are implementation specific and depends on the fabrication technology being implemented including, for example, the thickness of bottom oxide 110. In an NMOS embodiment employing a 5 to 10 nm bottom dielectric layer, V_{P1} and V_{P2} may be in the range of approximately 6 to 9 V, V_{R1} and V_{R2} in the range of approximately 3 to 6V, V_{E1} in the range of approximately −6 to −9 V, and V_{E2} in the range of approximately 6 to 9 V. It will be appreciated by those skilled in the design of electrically programmable storage cells that circuits capable of producing the required programming, erase, and read biasing conditions are well known.

Storage device 100 as depicted in FIG. 7 uses HCI programming and is limited to 2 bits/cell as described above. Additional processing as described below with respect to FIG. 8 through FIG. 12 may be performed to form a storage device capable of storing more than two bits per cell with increasing the size of the cell. In FIG. 8, control gate layer 140 is polished by CMP, etched backed, or a combination thereof to form two distinct control gates 145, each residing in a corresponding trench 108 (FIG. 6) in semiconductor substrate 102. In the depicted implementation, the polish of control gate layer 140, in addition to creating distinct control gates 145, also removes the portions of top dielectric 130 and DSEs 120 that are exterior to trenches 108, but stops on hard mask layer 106.

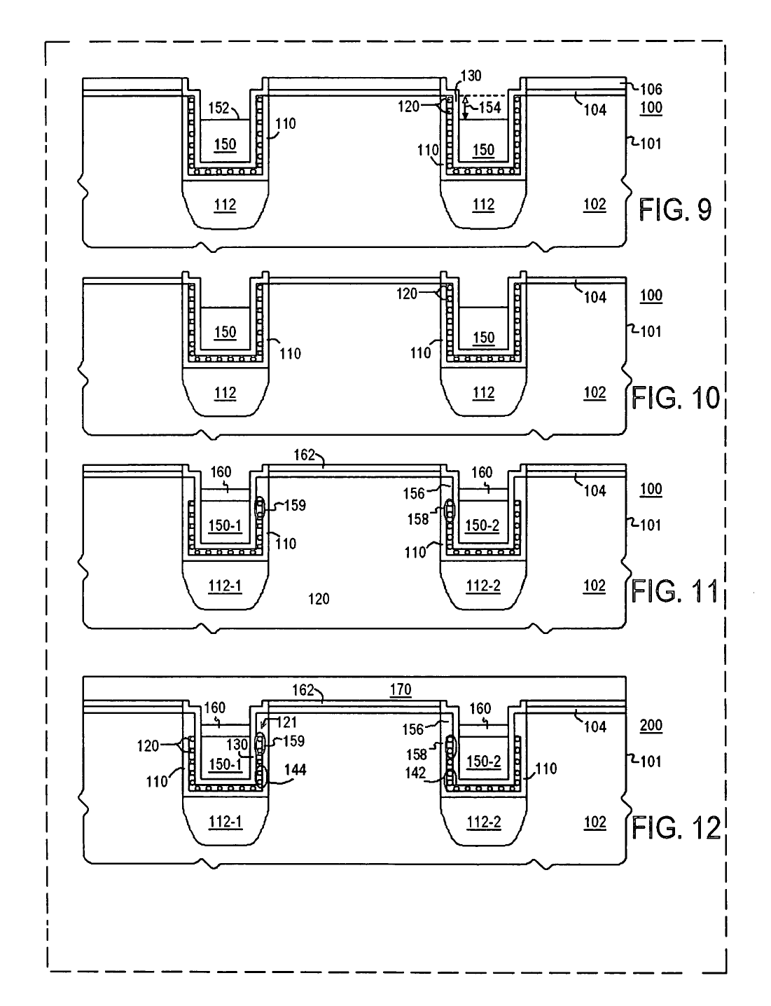

In FIG. 9, the control gates 145 of FIG. 8 are partially etched or otherwise removed to create recessed control gates 150. For embodiments in which the control gate material is polysilicon, recessed control gates 150 are formed by a known silicon etch process that is selective to the hard mask 106. An upper surface 152 of recessed control gates 150 is vertically displaced below an upper surface of semiconductor substrate 102 resulting in the presence of a gap 154 between upper surface 152 and an upper surface of semiconductor substrate 102. Importantly for purposes of employing a secondary programming technique to increase the number of storable bits in storage device 100, gap 154 exposes a portion of top oxide 130, which will facilitate a subsequent intentional oxidation of the DSEs 120 within gap 154 as a means of creating a structure suitable for employing source side injection programming (described below).

As depicted in FIG. 10, hard mask 106 is removed in preparation for a subsequent thermal oxidation process. In some embodiments, it is desirable to increase the thickness of dielectric liner 104 during the forthcoming thermal oxidation and the removal of a silicon nitride hard mask 106 is needed to achieve that objective. In these embodiments, hard mask 106 is removed by a conventional silicon nitride strip process (e.g., a hot phosphoric acid dip).

In FIG. 11, a thermal oxidation process is performed to form an oxide film 160 referred to herein as a control gate oxide 160 or isolating dielectric 160. Control gate oxide 160 provides isolation for recessed control gate 150. The thermal oxidation also adds a layer 162 of oxide to the existing dielectric liner 104. In addition, the thermal oxidation process oxidizes the silicon DSEs 120 within gap 154 (seen in FIG. 9) to produce an oxide gap structure 156 vertically adjacent to DSEs 120.

Upon completion of the storage cell as described below, oxide gap structure 156 facilitates source side injection (SSI) by causing electrons in the vicinity of oxide gap structure 156 to accelerate under appropriate biasing (described below). Some of these accelerated electrons will be injected into the DSEs 120 proximal to the gap structure 156 and thereby program these DSEs. The DSEs 120 programmed by SSI in this manner are located in an injection region indicated in FIG. 11 by reference numeral 158 for a configuration in which source/drain region 112-2 is the drain terminal

In FIG. 12, a select gate interconnect 170 is formed to complete a 4-bit per cell storage device 200. Select gate interconnect 170 may be a polysilicon interconnect or conventional metal interconnect (e.g., aluminum, copper, and the like). Storage device 200 as depicted in FIG. 12 includes a semiconductor substrate 102 that defines a trench (108 as seen in FIG. 6) and a bottom dielectric 110 lining the trench. A charge storage layer 121 lies on bottom dielectric 110. and includes a set of discontinuous storage elements (DSEs) 120. Top dielectric 130 and a conductive (e.g., polysilicon) control gate 150 lie on the DSEs 120. A source/drain region 112 (also referred to as diffusion region 112) is located under the trench. DSEs 120 are preferably polysilicon nanocrystals.

Turning to FIG. 14, an SSI programming table 155 for storage device 200 is depicted. According to the depicted embodiment of table 155, programming the SSI injection region 149 of device 200 may be achieved by biasing source/drain region 112-2 to a third programming voltage V_{P3}, first control gate 150-1 to a fourth programming voltage (V_{P4}) control gate 150-2 to a fifth programming voltage V_{P5}, select gate 170 to a sixth programming voltage (V_{P6}), and biasing source/drain region 112-1 and semiconductor layer 102 to 0 V. In one embodiment, V_{P3} is 6 V, V_{P4} is 8 V, V_{P5} is 5 V, and V_{P6} is 3 V. Programming SSI injection region 158 of device 200 may be achieved by biasing source/drain region 112-2 to V_{P3}, first control gate 150-1 to V_{P5}, second control gate 150-2 to V_{P4}, select gate 170 to a sixth programming voltage V_{P6}, and source/drain region 112-1 and semiconductor layer 102 to 0 V. Table 155 further indicates that the conditions for programming HCI injection region 142 of device 200 include biasing control gate 150-1, control gate 150-2, and select gate 170 to V_{P2}, source/drain region 112-2 to V_{P2}, and source/drain region 112-1 and semiconductor layer 102 to 0 V. Programming HCI injection region 144 of device 200 includes biasing control gate 150-1, control gate 150-2, and select gate 170 to V_{P2}, source/drain region 112-1 to V_{P2}, and source/drain region 112-2 and semiconductor layer 102 to 0 V.

In the depicted embodiment of storage device 200, control gate 150 is recessed within the trench (an upper surface of the control gate is vertically displaced below an upper surface of the substrate) and a control gate oxide 160 lies on conductive control gate 150. An upper most of the DSEs is vertically aligned to the control gate upper surface such that an oxide gap structure 156, laterally aligned with the DSEs 120 that are adjacent to the trench sidewall, and extending vertically from the upper most of DSEs 120 to the substrate upper surface.

The layer 121 of DSEs 120 include at least two, separately programmable injection regions (142, 144, 158, and 159). The injection regions are programmed by appropriate biasing of control gate 150, source/drain regions 112, and semiconductor substrate 102. The injections regions shown in FIG. 12 include HCI programmable injection regions 142 and 144 and SSI programmable regions 158 and 159. As depicted in FIG. 12, where the unit cell extends from the center of a first source/drain region 112 to a center of the adjacent source/drain region, the cell 200 includes four programmable bits. In embodiments that do not include the oxide gap structure 156, cell 200 includes the two HCI programmable injection regions 142 and 144.

In the foregoing specification, the invention has been described with reference to specific embodiments. However, one of ordinary skill in the art appreciates that various modifications and changes can be made without departing from the scope of the present invention as set forth in the claims below. For example, although the depicted embodiment is an NMOS transistor embodiment, PMOS embodiments are equally encompassed. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor fabrication process, comprising:
forming a trench in a semiconductor substrate;
lining the trench with a bottom dielectric;
forming a layer of discontinuous storage elements (DSEs) over the bottom dielectric and a top dielectric over the layer of DSEs;
forming a conductive control gate over the top dielectric; and
forming a source/drain region in the substrate underlying the trench.

2. The method of claim 1, wherein forming the trench includes
depositing an oxide liner on the substrate and a hard mask on the oxide liner;
patterning the oxide liner and the hard mask to expose a portion of the semiconductor substrate; and
etching the exposed portion of the substrate.

3. The method of claim 1, wherein lining the trench comprising thermally oxidizing sidewalls of the trench.

4. The method of claim 1, wherein forming the layer of DSEs comprises forming a layer of silicon nanocrystals.

5. The method of claim 4, wherein forming the top dielectric comprises performing a high temperature oxide process to deposit an oxide on the layer of silicon nanocrystals.

6. The method of claim 1, wherein forming the conductive control gate includes depositing a control gate layer of polysilicon.

7. The method of claim 6, further comprising, etching back the control gate layer to produce a recessed control gate within the trench, wherein an upper surface of the recessed control gate is vertically displaced below an upper surface of the semiconductor substrate.

8. The method of claim 7, further comprising thermally oxidizing an upper portion of the control gate to form a control gate oxide.

9. The method of claim 8, wherein thermally oxidizing an upper portion of the control gate includes oxidizing a portion of the DSEs.

10. A storage cell, comprising;
a semiconductor substrate defining a trench;
a bottom dielectric lining the trench;
a charge storage layer over the bottom dielectric including a plurality of discontinuous storage elements (DSEs);
a top dielectric overlying the layer of DSEs;
a conductive control gate over the top dielectric including at least a portion located in the trench; and
a diffusion region underlying the trench.

11. The storage cell of claim 10, wherein the DSEs comprise silicon nanocrystals.

12. The storage cell of claim 11, wherein the conductive control gate comprises polysilicon;

13. The storage cell of claim 12, further comprising a control gate oxide on the conductive control gate.

14. The storage cell of claim 13, wherein an upper surface of the control gate is vertically displaced below an upper surface of the semiconductor substrate and further wherein an upper most of the polysilicon nanocrystals is vertically aligned approximately to the control gate upper surface.

15. The storage cell of claim 14, further comprising an oxide gap structure laterally aligned with the polysilicon nanocrystals adjacent the trench sidewall and extending vertically from the upper most of the polysilicon nanocrystals to the upper surface of the substrate.

16. The storage cell of claim 10, further comprising a second source/drain region in the substrate, and wherein the layer of DSEs include at least programmable two injection regions wherein biasing the control gate, source/drain regions, and semiconductor substrate in a first biased state programs a first of the injection regions and wherein biasing the control gate, source/drain regions, and semiconductor substrate in a second biased state programs a second of the injection regions.

17. A method of fabricating a storage device, comprising:
forming first and second trenches in a semiconductor substrate;
forming a source/drain regions underlying the first and second trenches;
lining the trenches with a bottom dielectric and a layer of discontinuous storage elements (DSEs) on the bottom dielectric;
forming a top dielectric over the layer of DSEs; and
forming a layer of control gate material in the first and second trenches overlying the top dielectric;

18. The method of claim 17, further comprising forming an oxide gap structure laterally aligned with the DSEs adjacent a sidewall of at least one of the trenches and vertically positioned between an upper most of the DSEs and upper surface of the substrate.

19. The method of claim 18, further comprising forming a control gate oxide overlying the control gate.

20. The method of claim 19, wherein the control gate oxide comprises polysilicon and where forming the oxide gap structure and forming the oxide gap structure occur simultaneously.
